(19) United States
(12) Patent Application Publication
(10) Pub. No.: US 2015/0263126 A1
(43) Pub. Date: Sep. 17, 2015

(54) SEMICONDUCTOR MEMORY DEVICE AND METHOD FOR MANUFACTURING THE SAME

(71) Applicant: Kabushiki Kaisha Toshiba, Minato-ku (JP)

(72) Inventors: Masao SHINGU, Yokkaichi (JP); Katsuyuki Sekine, Yokkaichi (JP)

(73) Assignee: Kabushiki Kaisha Toshiba, Minato-ku (JP)

(21) Appl. No.: 14/644,800

(22) Filed: Mar. 11, 2015

(30) Foreign Application Priority Data
Mar. 17, 2014 (JP) 2014-054086

(51) Int. Cl. H01L 29/51; H01L 29/66; H01L 21/3105; H01L 27/115; H01L 21/285; H01L 29/423; H01L 21/28; H01L 29/788; H01L 21/311

(52) U.S. Cl. CPC H01L 29/518; H01L 29/7889; H01L 29/66825; H01L 21/3105; H01L 21/31111; H01L 21/28518; H01L 29/513; H01L 29/42324; H01L 21/28273; H01L 27/11519; H01L 27/11521; H01L 27/11556; H01L 29/66833; H01L 21/28282; H01L 27/11582

(57) ABSTRACT

According to one embodiment, a plurality of electrode films, a semiconductor pillar, a tunnel insulating film, a charge storage film, and a block insulating film. The plurality of electrode films are arranged to be separated each other along a first direction. The block insulating film includes a silicon oxide layer, and a high dielectric constant layer made of high dielectric constant material having a dielectric constant higher than a dielectric constant of silicon oxide. The high dielectric constant layer has a first portion and a second portion. The first portion is disposed between the semiconductor pillar and a space between the electrode films. The second portion is disposed between the semiconductor pillar and the electrode films. In a direction perpendicular to the first direction, a thickness of the first portion is thinner than a thickness of the second portion.

### CROSS-REFERENCE TO RELATED APPLICATIONS

This application is based upon and claims the benefit of priority from Japanese Patent Application No. 2014-054086, filed on Mar. 17, 2014; the entire contents of which are incorporated herein by reference.

### FIELD

Embodiments described herein relate generally to a semiconductor memory device and a method for manufacturing the same.

### BACKGROUND

A planar type NAND flash memory has been conventionally developed by forming a plurality of active areas on a silicon substrate, providing gate electrodes extending in a direction orthogonal to the active areas, and forming a memory cell on every cross-point of the active areas and the gate electrodes. However, in a planar type memory device like this, high integration is approaching to a limit due restriction of micro-fabrication technique.

Then, a stacked type NAND flash memory with memory cells stacked three-dimensionally has been proposed recently. Such a memory device can be constituted by forming a stacked body with an insulating film and an electrode film alternately stacked, forming a piercing hole in the stacked body, forming a memory film being able to store a charge on an inner surface of the piercing hole, and forming a silicon pillar inside the piercing hole to form the memory cell between the silicon pillar and the electrode film.

### BRIEF DESCRIPTION OF THE DRAWINGS

FIG. 1 is a perspective view illustrating a semiconductor memory device according to a first embodiment;

FIG. 2A is a cross-sectional view illustrating the semiconductor memory device according to the first embodiment, FIG. 2B is a partially enlarged cross-sectional view showing a region A shown in FIG. 2A;

FIGS. 3A and 3B are cross-sectional views illustrating a method for manufacturing the semiconductor memory device according to the first embodiment;

FIGS. 4A and 4B are cross-sectional views illustrating the method for manufacturing the semiconductor memory device according to the first embodiment;

FIGS. 5A and 5B are cross-sectional views illustrating the method for manufacturing the semiconductor memory device according to the first embodiment;

FIG. 6A is a partially enlarged cross-sectional view showing the region A shown in FIG. 5A, FIG. 6B is a partially enlarged cross-sectional view showing the region A shown in FIG. 5B;

FIGS. 7A and 7B are cross-sectional views illustrating the method for manufacturing the semiconductor memory device according to the first embodiment;

FIG. 8 is a cross-sectional view illustrating the effect of the first embodiment;

FIG. 9 is a perspective view illustrating a semiconductor memory device according to a second embodiment;

FIG. 10 is a cross-sectional view illustrating a method for manufacturing a semiconductor memory device according to a third embodiment;

FIG. 11 is a cross-sectional view illustrating a method for manufacturing a semiconductor memory device according to a fourth embodiment; and

FIG. 12A is a cross-sectional view illustrating a semiconductor memory device according to a fifth embodiment, FIG. 12B is a cross-sectional view illustrating a method for manufacturing the semiconductor memory device according to the fifth embodiment.

### DETAILED DESCRIPTION

According to one embodiment, a semiconductor memory device includes a plurality of electrode films, a semiconductor pillar, a tunnel insulating film, a charge storage film, and a block insulating film. The plurality of electrode films are arranged to be separated each other along a first direction. The semiconductor pillar extends in the first direction and pierces the plurality of electrode films. The tunnel insulating film is provided on a side surface of the semiconductor pillar. The charge storage film is provided on a side surface of the tunnel insulating film. The block insulating film is provided on a side surface of the charge storage film. The block insulating film includes a silicon oxide layer, and a high dielectric constant layer made of high dielectric constant material having a dielectric constant higher than a dielectric constant of silicon oxide. The high dielectric constant layer has a first portion and a second portion. The first portion is disposed between the semiconductor pillar and a space between the electrode films. The second portion is disposed between the semiconductor pillar and the electrode films. A thickness of the first portion in a direction perpendicular to the first direction is thinner than a thickness of the second portion in the perpendicular direction.

According to one embodiment, a method for manufacturing a semiconductor memory device is disclosed. The method can include stacking conductive films and a first film alternately along a first direction. The method can include forming a hole extending in a first direction and piercing the conductive films and the first film. The method can include forming a block insulating film on a side surface of the hole. The block insulating film includes a silicon oxide layer and a high dielectric constant layer. The high dielectric constant layer is made of a high dielectric constant material. The high dielectric constant material has a dielectric constant higher than a dielectric constant of silicon oxide. The method can include forming a charge storage film on a side surface of the block insulting film. The method can include forming a tunnel insulating film on a side surface of the charge storage film. The method can include forming a semiconductor pillar on a side surface of the tunnel insulating film. The method can include forming a slit in the stacked body. The method can include removing the first film through the slit. In addition, the method can include removing at least a part of a portion of the high dielectric constant layer. The portion is disposed between the semiconductor pillar and a space between the conductive films.

Various embodiments will be described hereinafter with reference to the accompanying drawings.

### First Embodiment

Firstly, the first embodiment will be described.

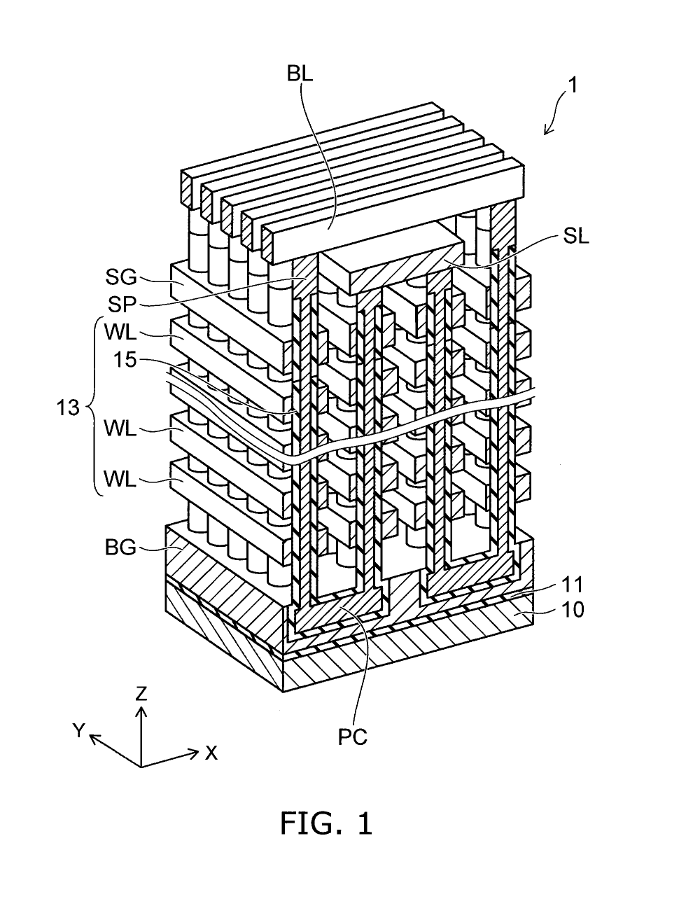

FIG. 1 is a perspective view illustrating a semiconductor memory device according to the embodiment.

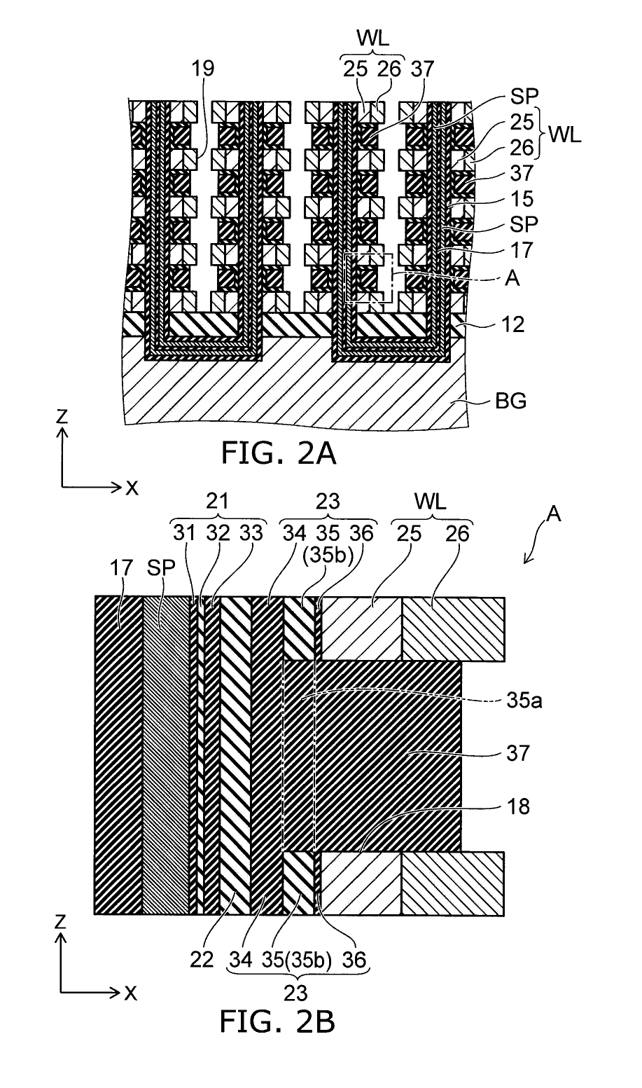

FIG. 2A is a cross-sectional view illustrating the semiconductor memory device according to the embodiment, FIG. 2B is a partially enlarged cross-sectional view showing a region A shown in FIG. 2A.

As shown in FIG. 1, in a semiconductor memory device 1 (hereinafter, simply referred to as “device 1” as well) according to the embodiment, a silicon substrate 10 is provided.

As described below, in the specification, an XYZ orthogonal coordinate system is adopted for convenience of description. Two directions parallel to an upper surface of the silicon substrate 10 and orthogonal each other are taken as “X-direction” and “Y-direction”, and a direction perpendicular to the upper surface of the silicon substrate 10, namely, a vertical direction is taken as “Z-direction”.

An insulating film 11 and a back gate electrode BG are provided on the silicon substrate 10. A pipe connector PC having a longitudinal direction in the X-direction and being nearly rectangular parallelepiped is provided in the back gate electrode BG. A plurality of control gate electrode films WL are stacked on the back gate electrode BG via interlayer insulating films 12 and constitute a stacked body 13. That is, in the stacked body 13, the plurality of control gate electrode films WL extend in the Y-direction and are arranged in the Z-direction spaced from one another.

A selection gate electrode SG extending in the Y-direction is provided on the stacked body 13. All the back gate electrode BG, the pipe connector PC, the control gate electrode films WL and the selection gate electrode SG are conductive films formed of silicon (Si) and containing an impurity, for example, boron (B). The back gate electrode BG shape is tabular, and the control gate electrode films WL shape and the selection gate electrode SG shape are band-like. A source line SL extending in the Y-direction and made of, for example, a metal is provided on the selection gate electrode SG. A bit line BL extending in the X-direction and made of, for example, a metal is provided on the source line SL.

A silicon pillar SP extending in the Z-direction is provided between the back gate electrode BG and the source line SL and between the back gate electrode BG and the bit line BL so as to pierce the stacked body 13 and the selection gate electrode SG. The silicon pillar SP connected to the source line SL and the silicon pillar SP connected to the bit line BL are connected each other through the pipe connector PC. A memory film 15 is provided on an outer surface of a structure formed of the silicon pillar SP and the pipe connector PC. This forms a memory cell on every cross-point portion of the silicon pillar SP and the control gate electrode films WL.

As shown in FIGS. 2A and 2B, the silicon pillar SP and the pipe connector PC are formed in a pipe shape, and an insulating member 17 made of, for example, silicon oxide is formed inside the pipe. The memory film 15 includes a tunnel insulating film 21, a charge storage film 22 and a block insulating film 23 stacked in order from the silicon pillar SP side. Although the tunnel insulating film 21 is usually insulative, when a prescribed voltage within a range of a driving voltage of the semiconductor memory device 1 is applied, an FN tunnel current flows in the tunnel insulating film 21. The charge storage film 22 is a film able to store a charge, and is formed of, for example, a material having an electron trap site. The block insulating film 23 is a film through which a current does not substantially flow, even if a voltage is applied within the range of the driving voltage of the device 1.

Furthermore, the control gate electrode film WL includes a polysilicon portion 25 disposed on the silicon pillar SP side and a silicide portion disposed on a side far from the silicon pillar SP. Here, “polysilicon portion” is a name showing a portion having polysilicon as a main component. It is much the same for names of other portions, layers, films or the like.

The tunnel insulating film 21 includes a silicon oxide layer 31, a silicon nitride layer 32 and a silicon oxide layer 33 stacked in order from the silicon pillar SP side. The charge storage film 22 is a monolayer film formed of silicon nitride. The block insulating film 23 includes a silicon oxide layer 34, a high dielectric constant layer 35 and a silicon oxide layer 36 stacked in order from the silicon pillar SP side. The high dielectric constant layer 35 is a layer made of a high dielectric constant material having a dielectric constant higher than a dielectric constant of silicon oxide. In the embodiment, the high dielectric constant material is silicon nitride. Here, a relative dielectric constant of silicon oxide (SiO₂) is approximately 3.9 and a relative dielectric constant of silicon nitride (Si₃N₄) is approximately 7.4.

The high dielectric constant layer 35 is provided continuously along the Z-direction between the control gate electrode films WL and the silicon pillar SP, however the high dielectric constant layer 35 is provided discontinuously along the Z-direction between the silicon pillar SP and a space 18 between the control gate electrode films WL. This divides the high dielectric constant layer 35 every control gate electrode film WL in the Z-direction. A silicon oxide layer 37 is provided in a portion between the high dielectric constant layers 35 in the Z-direction and the space 18 between the control gate electrode films WL. A space between the control gate electrode films WL adjacent in the X-direction and a space between the silicon oxide films 37 adjacent in the X-direction form a slit 19 spreading in a XZ-plane.

More generally, in a direction perpendicular to the Z-direction, an average thickness of a portion 35a disposed between the space 18 and the silicon pillar SP in the high dielectric constant layer 35 is thinner than an average thickness of a portion 35b disposed between the control gate electrode films WL and the silicon pillar SP in the high dielectric constant layer 35. The embodiment includes a special case where the portion 35a has a portion with zero thickness and the portion 35b are separated each other. In this case, the high dielectric constant layer 35 is divided in the portion 35a along the Z-direction.

Next, a method for manufacturing the semiconductor memory device according to the embodiment will be described.

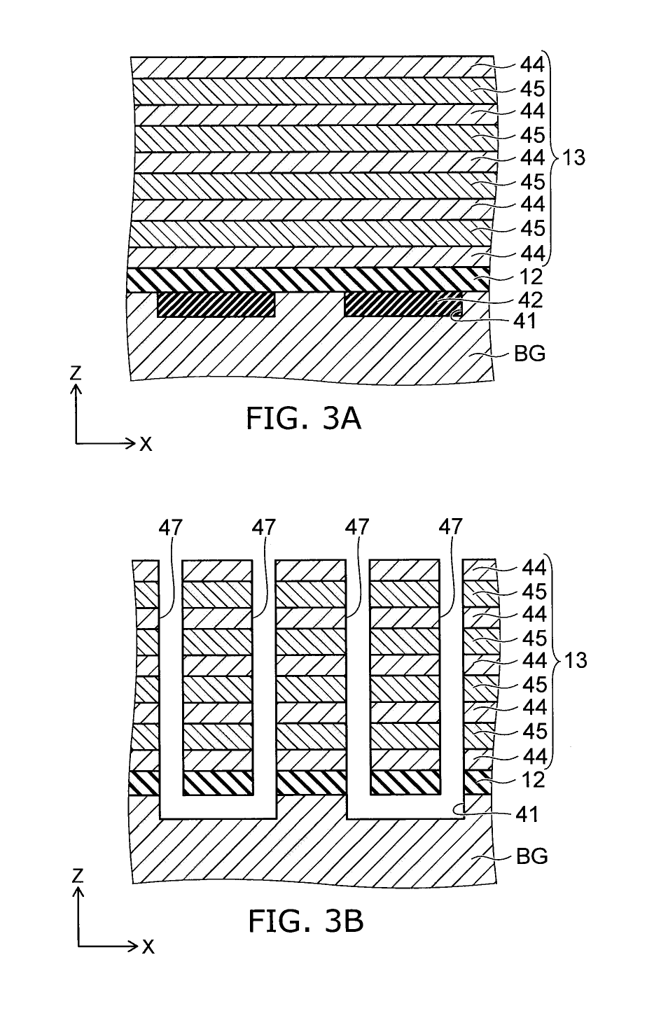

FIGS. 3A and 3B, FIGS. 4A and 4B, FIGS. 5A and 5B, FIGS. 6A and 6B, and FIGS. 7A and 7B are cross-sectional views illustrating the method for manufacturing the semiconductor memory device according to the embodiment.

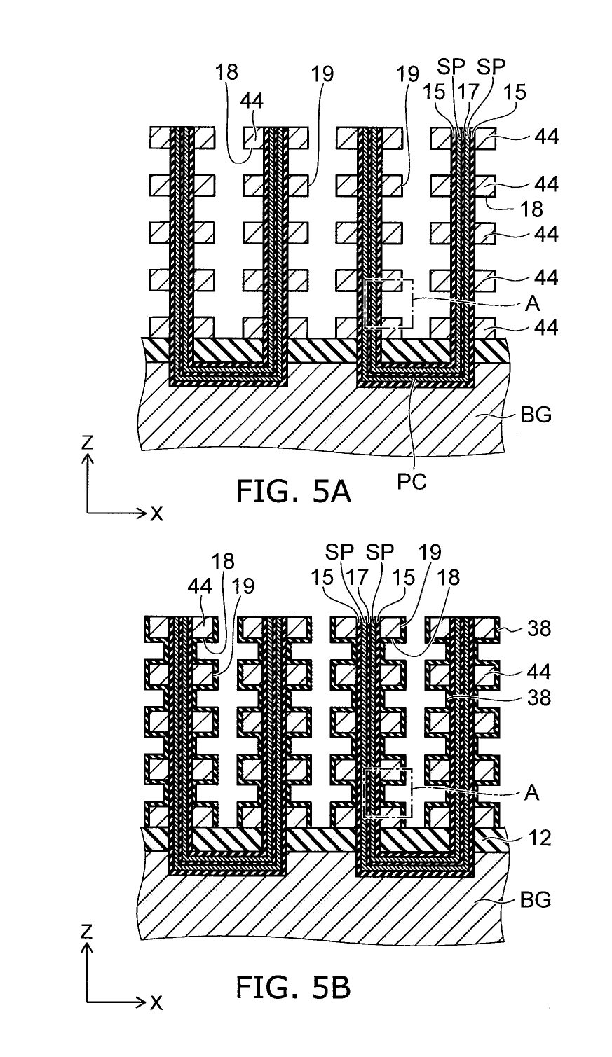

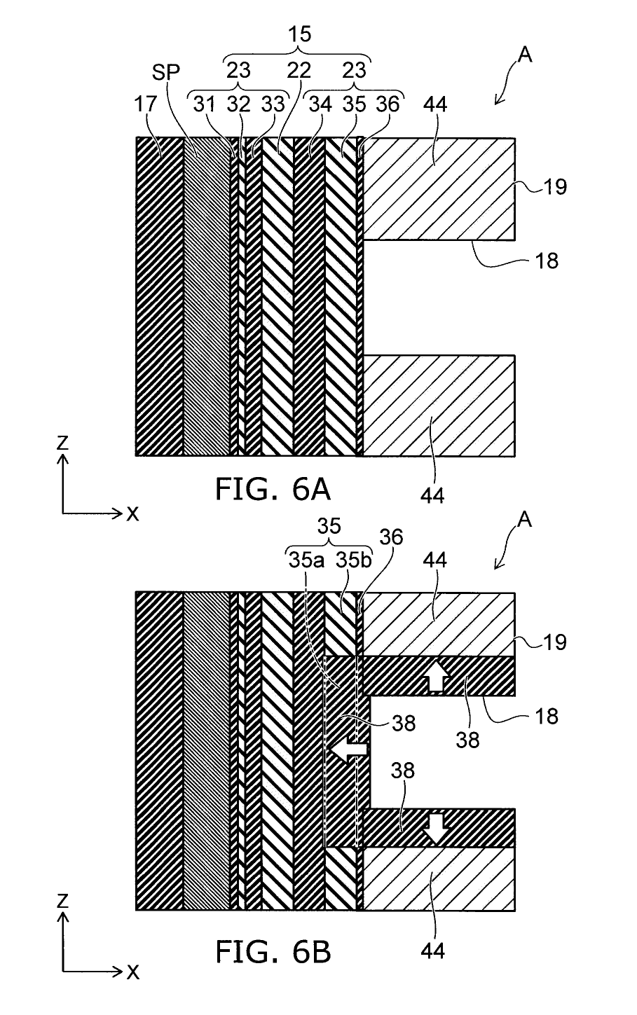

FIG. 6A is a partially enlarged cross-sectional view showing a region A shown in FIG. 5A, FIG. 6B is a partially enlarged cross-sectional view showing the region A shown in FIG. 5B.

Firstly, as shown in FIG. 1, the insulating film 11 is formed on the silicon substrate 10, and the back gate electrode BG is formed.

Next, as shown in FIG. 3A, recesses 41 having a longitudinal direction in the X-direction and being nearly rectangular parallelepiped are formed in a matrix on an upper surface of the back gate electrode BG. Next, a sacrificial material 42 made of, for example, silicon nitride is buried in the recess 41. Next, an interlayer insulating film 12 is formed on the back gate electrode BG and the sacrificial material 42.

Next, a boron-doped polysilicon film 44 and a non-doped polysilicon film 45 are alternately formed to form the stacked body 13. The boron-doped polysilicon film 44 is a film serving as the control gate electrode film WL in a later process, and is not always needed to be formed from boron-doped polysilicon. A conductive film enable to be processed may be used. The non-doped polysilicon film 45 is a sacrificial film to be removed in a later process, and is not always needed to be formed from non-doped polysilicon. A film favorable for obtaining an etching selection ratio to the boron-doped polysilicon film 44 and the interlayer insulating film 12 may be used.

Next, as shown in FIG. 3B, a hole 47 extending in the Z-direction is formed in the stacked body 13. The holes 47 are formed in a matrix to reach both ends of the recess 41 in the X-direction. Next, wet etching is performed via the hole 47, and thus the sacrificial material 42 is removed from the recess 41. This communicates the hole 47 with the recess 41.

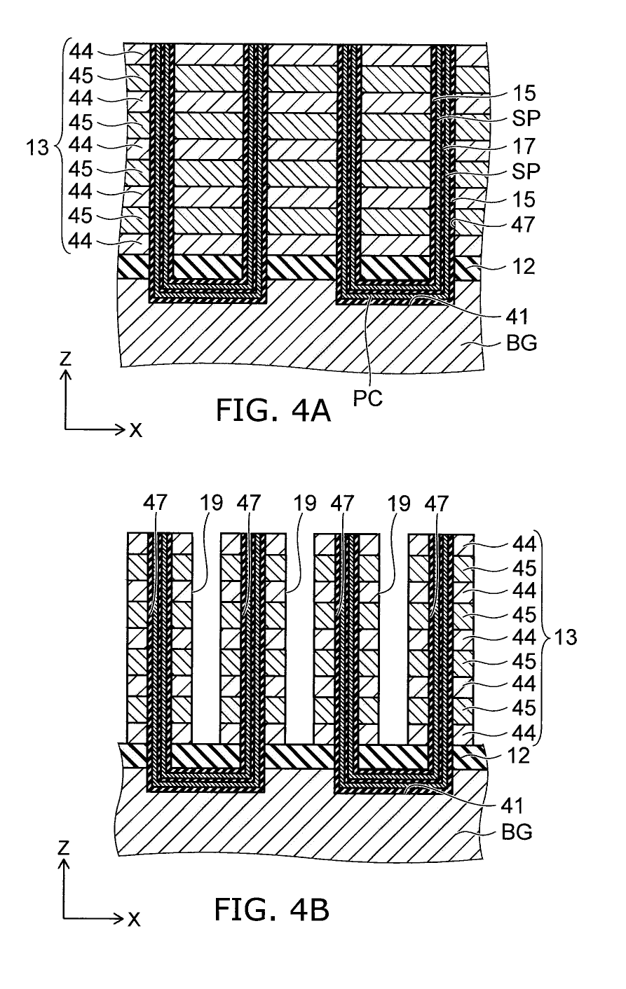

Next, as shown in FIG. 4A and FIG. 2A, a high dielectric constant material, for example, the high dielectric constant layer 35 made of silicon nitride is formed on a side surface of the hole 47 and an inner surface of the recess 41. In this step, the high dielectric constant layer 35 is formed continuously along the side surface of the hole 47. At this time, the silicon oxide layer 36 is formed inevitably. Next, the silicon oxide layer 34 is formed on the side surface of the high dielectric constant layer 35. The silicon oxide layer 36, the high dielectric constant layer 35, and the silicon oxide layer 34 form the block insulating layer 23. Next, silicon nitride is illustratively deposited on a side surface of the block insulating film 23 to form the charge storage film 22. Next, the silicon oxide layer 33, the silicon nitride layer 32 and the silicon oxide layer 31 are sequentially formed on a side surface of the charge storage film 22, and thus the tunnel insulating film 21 is formed. This forms the memory film 15 on the inner surfaces of the hole 47 and the recess 41.

Next, amorphous silicon is deposited on a side surface of the tunnel insulating film 21 to form the silicon pillar SP cylindrically in the hole 47, and the pipe connector PC is formed in a square tube shape in the recess 41. Next, silicon oxide is illustratively buried in a space surrounded by the silicon pillar SP to form the insulating member 17.

Next, as shown in FIG. 4B, the slit 19 extending in the Y-direction is formed in the stacked body 13 by, for example, a lithography method and a RIE (Reactive Ion Etching) method. The slit 19 is formed so as to pass through between the holes 47 adjacent in the X-direction.

Next, as shown in FIG. 5A and FIG. 6A, wet etching based on TMY (choline aqueous solution) is performed via the slit 19, and thus the non-doped polysilicon film 45 is removed. This forms the space 18 between the boron-doped polysilicon films 44 in the Z-direction, and the silicon oxide layer 36 of the block insulating film 23 is exposed to the space 18.

Next, as shown in FIG. 5B and FIG. 6B, radical oxidation treatment is performed. More specifically, oxidation treatment based on oxygen active species of ozone, a mixed gas of oxygen gas and a hydrogen gas, oxygen plasma or the like is performed. Thereby, oxygen active species pass through the slit 19 and the space 18 to reach the silicon oxide layer 36, diffuse in the silicon oxide layer 36, and oxidize the high dielectric constant layer 35 made of silicon nitride.

As a result, the portion 35a disposed between the space 18 and the silicon pillar SP in the high dielectric constant layer 35 is oxidized to change to a silicon oxide layer 38. Therefore, the portion 35a as the high dielectric constant layer is removed. At this time, it is estimated that nitrogen contained in the portion 35a is exhausted outside in the radical oxidation process via the space 18 and the slit 19. As a result, the high dielectric constant layer 35 leaves the portion disposed between the boron-doped polysilicon film 44 and the silicon pillar SP, and is divided every boron-doped polysilicon film 44 along the Z-direction. At this time, an exposed surface of each boron-doped polysilicon film 44 is also oxidized to form the silicon oxide layer 38. Therefore, a thickness of each boron-doped polysilicon film 44, namely, a length in the Z-direction decreases.

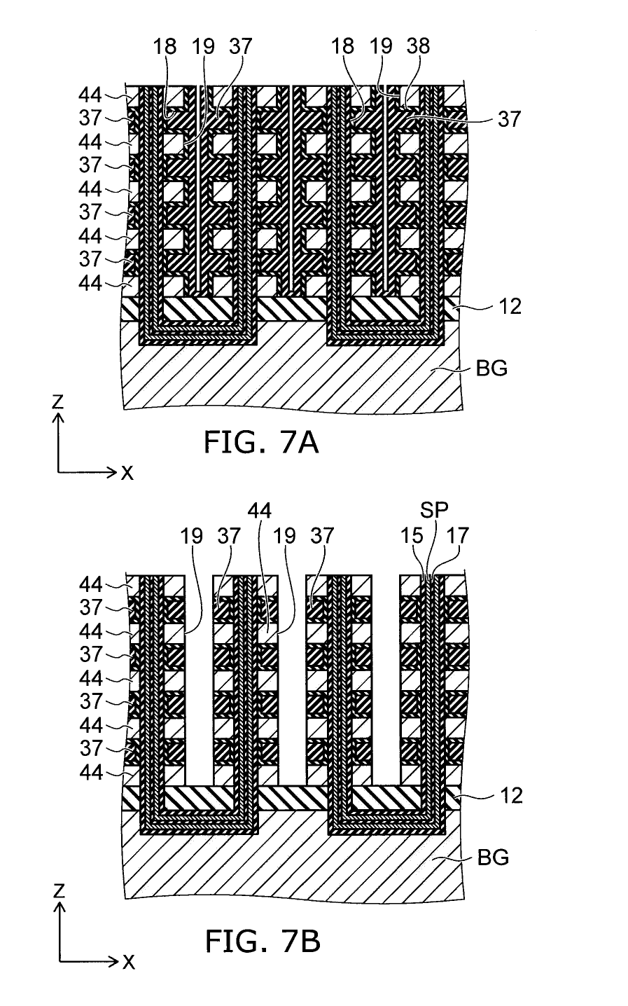

Next, as shown in FIG. 7A, silicon oxide is deposited in the space 18 and the slit 19 to form the silicon oxide film 37. Hereinafter, the silicon oxide layer 38 is described as a portion of the silicon oxide film 37. A low dielectric constant film (Low-k film) may be formed in place of the silicon oxide film 37.

Next, as shown in FIG. 7B, for example, wet etching based on DHF (diluted hydrofluoric acid) is performed, and thus the silicon oxide film 37 is etched back and is left only in the space 18. This exposes the boron-doped polysilicon film 44 again to the inner surface of the slit 19.

Next, as shown in FIGS. 2A and 2B, a metal is deposited on the inner surface of the slit 19 and is subjected to a heat treatment, and thus is caused to react with the boron-doped polysilicon film 44, and thereafter silicide treatment is performed to the boron-doped polysilicon film 44 by removing unreacted metal. This changes a portion of the boron-doped polysilicon film 44 to the silicide portion 26. At this time, the unreacted boron-doped polysilicon film 44 forms the polysilicon portion 25. In this way, the control gate electrode films WL are formed.

Next, as shown in FIG. 1, by using an ordinary method, an upper structure of the selection gate electrode film SG, the source line SL and the bit line BL or the like is formed. The silicon oxide film 37 forms a portion of the interlayer insulating film 12. In this way, the semiconductor device 1 of the embodiment is manufactured.

Next, the effect of the embodiment is described.

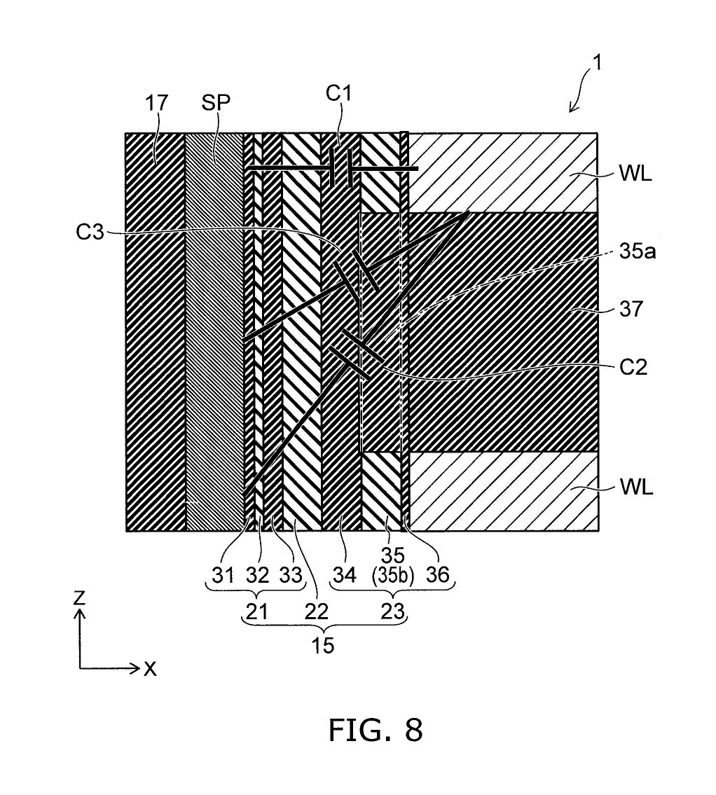

FIG. 8 is a cross-sectional view illustrating the effect of the embodiment.

As shown in FIG. 8, in the semiconductor device 1 of the embodiment, the high dielectric constant layer 35 having a higher dielectric constant than silicon oxide is provided, and thus a capacitance C1 between the control gate electrode film WL and the silicon pillar SP can be increased in each memory cell and a high coupling efficiency can be realized. A back tunnel current going toward the silicon pillar SP from the control gate electrode film WL can be suppressed and erase saturation of the memory cell can be improved.

On the other hand, in the embodiment, the portion 35a is replaced by the silicon oxide film 37 by performing the radical oxidation treatment to the high dielectric constant layer 35. Thereby, a dielectric constant of the portion where the portion 35a exists is decreased and a parasite capacitance C2 between the memory cells adjacent in the Z-direction can be reduced. This reduces parasite coupling between the memory cells, and suppresses interference between the memory cells, and thus is able to prevent malfunction.

The portion 35a of the high dielectric constant layer 35 is replaced with the silicon oxide film 37, and thus a parasite capacitance C3 between the control gate electrode film WL and the portion disposed between the memory cells of the silicon pillar SP is reduced, and the parasite coupling can be suppressed. Thereby, charges are prevented from injecting into the portion disposed between the memory cells in the charge storage film 22, and the operation can be stabilized.

Furthermore, in the embodiment, the slit 19 is formed in the stacked body 13 in a process shown in FIG. 4B, and the etching is performed via the slit 19 in a process shown in FIG. 5A, and thus the non-doped polysilicon film 45 is removed and the block insulating film 23 is exposed to the space 18, in addition, the portion 35a of the high dielectric constant film 35 is oxidized and disappeared by performing the radical oxidation treatment in a process shown in FIG. 6B. This removes the portion 35a disposed between the memory cells in the high dielectric constant layer 35 extending in the Z-direction, and the portion 35b disposed in the memory cells can be remained. As a result, in the semiconductor memory device 1 which integrates the memory cells three-dimensionally, the high dielectric constant layer 35 provided along the Z-direction can be processed collectively with self-alignment.

### Second Embodiment

Next, a second embodiment will be described.

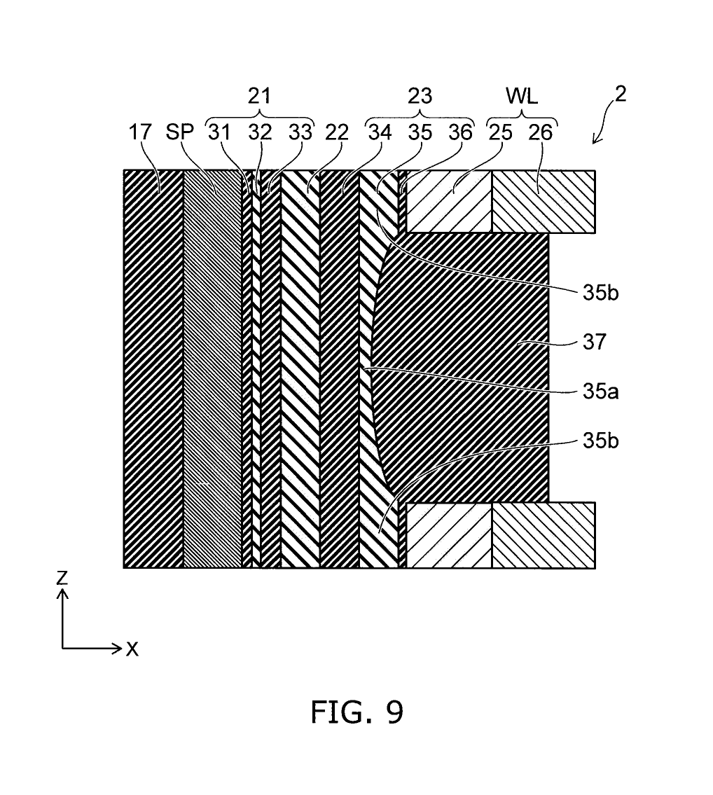

FIG. 9 is a cross-sectional view illustrating a semiconductor memory device according to the embodiment.

As shown in FIG. 9, in the semiconductor memory device 2 according to the embodiment, oxidation reaction of the portion 35a of the high dielectric constant layer 35 does not pierce in the thickness direction, and a part of the portion 35a in the thickness direction is remained as unreacted. For this reason, the high dielectric constant layer 35 is not divided in the Z-direction, and exists continuously. However, since a part of the portion 35a is oxidized, an average film thickness of the portion 35a is thinner than an average film thickness of the portion 35b. The device 2 like this can be manufactured by stopping the radical oxidation treatment before the portion 35a pierces in a process shown in FIG. 6B.

Also in the embodiment, compared with the case where the portion 35a is not removed at all, the parasite capacitances C2 and C3 shown in FIG. 8 are reduced, and thus a definite effect can be obtained. In the embodiment, radical oxidation treatment time is short compared with the first embodiment, and thus productivity is high. Constitution, manufacturing method, and effects other than those above in the embodiment are the same for the first embodiment described previously.

### Third Embodiment

Next, a third embodiment will be described.

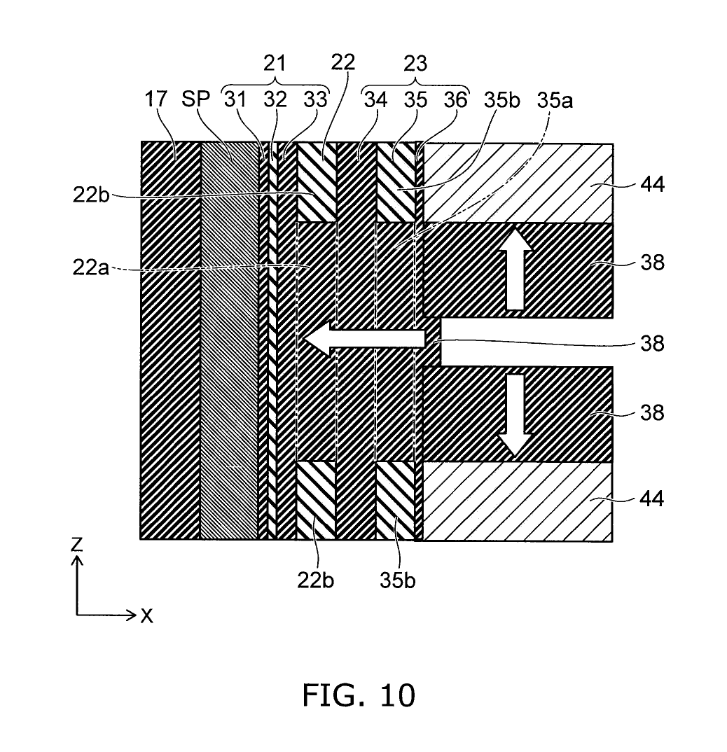

FIG. 10 is a cross-sectional view illustrating a method for manufacturing a semiconductor memory device according to the embodiment.

As shown in FIG. 10, in the process of the radical oxidation treatment of the embodiment, not just high dielectric constant layer 35 of the block insulating film 23 but the charge storage film 22 disposed in the back is oxidized as well. The oxidation of the charge storage film 22 proceeds through that the oxygen active species arriving at the silicon oxide layer 38 via the slit 19 and the space 18 diffuse in the silicon oxide layer 38 and the silicon oxide layer 34 formed by oxidation of the high dielectric constant layer 35 and arrive at a portion 22a of the charge storage film 22.

Thereby, in the radical oxidation process, the portion 22a disposed between the space 18 and the silicon pillar SP in the charge storage film 22 is removed and a portion 22b disposed between the boron doped polysilicon film 44 and the silicon pillar SP in the charge storage film 22 is remained. This separates the portions 22b arranged along the Z-direction.

According to the embodiment, since the charge storage film 22 can be divided every memory cell, the charge stored in the charge storage film 22 in a certain memory cell can be prevented from conducting in the charge storage film 22 and transferring to other memory cells. This can improve data retention characteristics. Constitution, manufacturing method, and effects other than those above in the embodiment are the same for the first embodiment described previously.

In the embodiment, it is allowed that the portion 22a of the charge storage film 22 is not removed completely and a portion is remained. In this case, since a portion located between the memory cells in the charge storage film 22 is thinner than a portion located in the memory cell, while charge retention ability is sufficiently confirmed in the memory cell, the charge transfer can be suppressed between the memory cells. Therefore, also in this case, the data retention characteristics can be improved.

In the embodiment, the process of the radical oxidation treatment may be alternately performed with the process of removing silicon oxide by the wet etching. The wet etching of removing silicon oxide includes, for example, the etching based on DHF as etching solution. In this way, after silicon oxide produced by the radical oxidation treatment is removed by the wet etching and the high dielectric constant layer 35 or the charge storage film 22 is newly exposed, the radical oxidation treatment can be performed again and the high dielectric constant layer 35 or the charge storage film 22 can be effectively oxidized. As a result, the charge storage film 22 located in the back can be surely oxidized without excessively increasing oxidation ability of the radical oxidation treatment.

### Fourth Embodiment

Next, a fourth embodiment will be described.

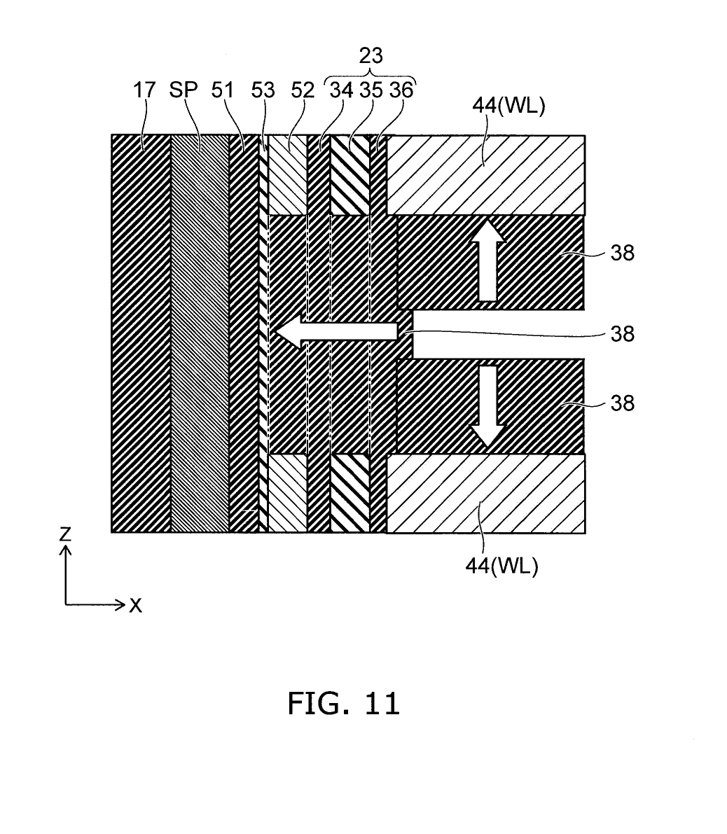

FIG. 11 is a cross-sectional view illustrating a method for manufacturing a semiconductor memory device according to the embodiment.

As shown in FIG. 11, the semiconductor memory device according to the embodiment is different from the semiconductor memory device (see FIG. 10) according to the third embodiment in a point that a charge storage film 52 made of polysilicon is provided in place of the charge storage film 22 (see FIG. 10) made of silicon nitride. In the charge storage film 52, a portion disposed between the silicon pillar SP and the space 18 between the control gate electrode films WL adjacent in the Z-direction is removed. Thereby, the charge storage film 52 is divided every control gate electrode film WL in the Z-direction.

In the semiconductor memory device according to the embodiment, a tunnel insulating film 51 made of a monolayer silicon oxide film is provided in place of the tunnel insulating film 21 (see FIG. 10) of ONO (Oxide-Nitride-Oxide) structure. An etching stopper layer 53 made of, for example, silicon nitride is provided between the tunnel insulating film 51 and the charge storage film 52.

In the embodiment, since the charge storage film 52 is divided every control gate electrode film WL in the Z-direction, the charge storage film 52 can be formed of a conductive material. That is, a floating gate can be constituted by the charge storage film 52. This allows the charge storage ability of each memory cell to be improved and the operation margin to be broad. Constitution, manufacturing method, and effects other than those above in the embodiment are the same for the third embodiment described previously. In the embodiment, the charge storage film 52 may be formed of a conductive material other than polysilicon, for example, may be formed of a metal.

### Fifth Embodiment

Next, a fifth embodiment will be described.

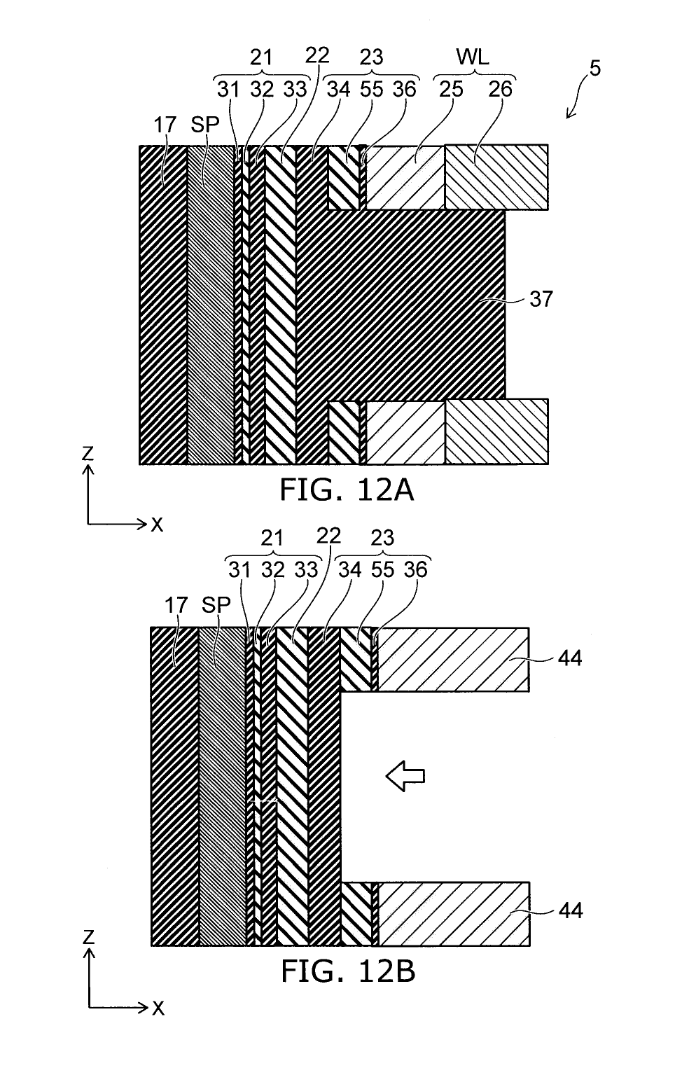

FIG. 12A is a cross-sectional view illustrating a semiconductor memory device according to the embodiment, FIG. 12B is a cross-sectional view illustrating a method for manufacturing the semiconductor memory device according to the embodiment.

As shown in FIG. 12A, a semiconductor memory device 5 according to the embodiment is different from the semiconductor device 1 (see FIG. 2B) according to the first embodiment in a point that a high dielectric constant layer 55 made of a metal oxide, for example, aluminum oxide (Al₂O₃) or hafnium oxide (HfO₂) is provided in place of the high dielectric constant layer 35 made of silicon nitride.

As described above, in the embodiment, the high dielectric constant layer 55 is formed of a metal oxide. Since the metal oxide cannot be disappeared by the radical oxidation treatment, the high dielectric constant layer 55 is selectively removed by, for example, the wet etching in place of the radical oxidation treatment in the embodiment.

That is, as shown in FIG. 12B, after removing the non-doped polysilicon film 45 (see FIG. 4B) to form the space 18, the portion disposed between the space 18 and the silicon pillar SP in the silicon oxide layer 36 and the portion between the space 18 and the silicon pillar SP in the high dielectric constant layer 55 are removed by performing the wet etching using the boron-doped polysilicon film 44 as a mask via the slit 19 and the space 18. Constitution, manufacturing method, and effects other than those above in the embodiment are the same for the first embodiment described previously.

Also in the embodiment, as well as the third embodiment described above, the charge storage film 22 may be selectively selected in addition to the high dielectric constant layer 55. For example, when the charge storage film 22 is formed of silicon nitride or polysilicon, the charge storage film 22 can be removed by performing the radical oxidation treatment after removing the high dielectric constant film 55. When the charge storage film 22 is formed of a metal or a metal oxide, the charger storage film 22 can be removed by performing the wet etching after removing the high dielectric constant film 55.

In the respective embodiments described above, an example of a U-shaped device including the pipe connector PC connecting the lower ends of the two silicon pillars SP is shown as the semiconductor device, however the semiconductor memory device is not limited thereto and, for example, may be an I-shaped device including the source line provided below the silicon pillar SP in a plate-like, a lower end of each silicon pillar being commonly connected to the source line, and an upper end of each silicon pillar SP being connected to the bit line.

In the respective embodiments described above, an example of the oxidation treatment of the high dielectric constant layer being performed by the radical oxidation is shown, however the oxidation treatment is not limited thereto, and may be a treatment capable of oxidizing the high dielectric constant layer to necessary degree. An oxidation treatment having high oxidation ability such as, for example, wet oxidation or the like may be performed in place of the radical oxidation.

According to the embodiments described above, a stably operating semiconductor memory device and a method for manufacturing the same can be achieved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor memory device, comprising:
a plurality of electrode films arranged to be separated each other along a first direction;
a semiconductor pillar extending in the first direction and piercing the plurality of electrode films;
a tunnel insulating film provided on a side surface of the semiconductor pillar;
a charge storage film provided on a side surface of the tunnel insulating film; and
a block insulating film provided on a side surface of the charge storage film,
the block insulating film including:
a silicon oxide layer; and
a high dielectric constant layer made of high dielectric constant material having a dielectric constant higher than a dielectric constant of silicon oxide, and
the high dielectric constant layer having a first portion and a second portion, the first portion being disposed between the semiconductor pillar and a space between the electrode films, the second portion being disposed between the semiconductor pillar and the electrode films, a thickness of the first portion in a direction perpendicular to the first direction being thinner than a thickness of the second portion in the perpendicular direction.

2. The device according to claim 1, wherein the high dielectric constant layer is divided in the first portion along the first direction.

3. The device according to claim 2, wherein
the charge storage film has a third portion and a fourth portion, the third portion is disposed between the semiconductor pillar and the space between the high dielectric constant layer, the fourth portion is disposed between the semiconductor pillar and the electrode films, a thickness of the third portion in the perpendicular direction is thinner than a thickness of the fourth portion in the perpendicular direction.

4. The device according to claim 3, wherein
the charge storage film is divided in the third portion along the first direction.

5. The device according to claim 4, wherein
the charge storage film is made of a conductive material.

6. The device according to claim 1, wherein
the high dielectric material is silicon nitride.

7. The device according to claim 1, further comprising:
an interlayer insulating film disposed in the space.

8. A semiconductor memory device, comprising:
a plurality of electrode films arranged to be separated each other along a first direction;
a semiconductor pillar extending in the first direction and piercing the plurality of electrode films;
a tunnel insulating film provided on a side surface of the semiconductor pillar;
a charge storage film provided on a side surface of the tunnel insulating film; and
a block insulating film provided on a side surface of the charge storage film,
the block insulating film including:
a silicon oxide layer; and
a high dielectric constant layer made of high dielectric constant material having a dielectric constant higher than a dielectric constant of silicon oxide, the high dielectric constant layer being disposed between the semiconductor pillar and one of the electrode films and not being disposed between the semiconductor pillar and a space between the electrode films.

9. A method for manufacturing a semiconductor memory device, comprising:
stacking conductive films and a first film alternately along a first direction;
forming a hole extending in a first direction and piercing the conductive films and the first film;
forming a block insulating film on a side surface of the hole, the block insulating film including a silicon oxide layer and a high dielectric constant layer, the high dielectric constant layer being made of a high dielectric constant material, the high dielectric constant material having a dielectric constant higher than a dielectric constant of silicon oxide;
forming a charge storage film on a side surface of the block insulting film;
forming a tunnel insulating film on a side surface of the charge storage film;
forming a semiconductor pillar on a side surface of the tunnel insulating film;
forming a slit in the stacked body;
removing the first film through the slit; and
removing at least a part of a portion of the high dielectric constant layer, the portion being disposed between the semiconductor pillar and a space between the conductive films.

10. The method according to claim 9, wherein
the high dielectric constant material is silicon nitride, and
the removing at least the part has a process of oxidation treatment.

11. The method according to claim 10, wherein
the oxidation treatment is radical oxidation treatment.

12. The method according to claim 11, wherein
the radical oxidation treatment is based on one or more active species selected from a group of ozone, a mixed gas of an oxygen gas and a nitrogen gas, and an oxygen plasma.

13. The method according to claim 9, wherein
in the removing at least the part, the high dielectric constant layer is divided every the conductive film.

14. The method according to claim 13, wherein
the charge storage film is made of silicon nitride, and
in the removing at least the part, at least a part of a portion of the charge storage film is removed, the portion is disposed between the semiconductor pillar and the space between the conductive films.

15. The method according to claim 13, wherein
the charge storage film is made of a conductive material, and
in the removing at least the part, a portion of the charge storage film is removed, the portion is disposed between the semiconductor pillar and the space between the conductive films.

16. The method according to claim 10, wherein
the removing at least the part further includes performing wet etching to the silicon oxide.

17. The method according to claim 9, wherein
the high dielectric constant material is a metal oxide, and
the removing at least the part includes performing wet etching to the metal oxide.

18. The method according to claim 9, further comprising:
silicidating the conductive film via the slit.

19. The method according to claim 9, further comprising:
embedding an interlayer insulating film into the space via the slit.
